(19) United States
(12) Patent Application Publication
(10) Pub. No.: US 2015/0010381 A1
(43) Pub. Date: Jan. 8, 2015

(54) WAFER PROCESSING CHAMBER AND METHOD FOR TRANSFERRING WAFER IN THE SAME

(71) Applicant: UNITED MICROELECTRONICS CORP., HSINCHU (TW)

(72) Inventor: Yan Cai, Singapore (SG)

(21) Appl. No.: 13/936,415

(22) Filed: Jul. 8, 2013

(51) Int. Cl. H01L 21/677; H01J 37/32

(52) U.S. Cl. CPC H01L 21/67745; H01J 37/32715
USPC 414/806; 156/345.54

(57) ABSTRACT

A wafer processing chamber and a method for transferring wafer in the same are provided to prevent the arcing issue. In the embodiments, a wafer is positioned on the focus ring, and a lifting apparatus is provided outside the wafer such as corresponding to the focus ring. The lifting apparatus of the embodiment could be positioned below or above the focus ring. The wafer and the focus ring are lifted together by the lifting apparatus, and transferred together by a transferring unit.

### BACKGROUND

1. Technical Field

The disclosure relates in general to a wafer processing chamber and a method for transferring wafer in the same, and more particularly to the wafer processing chamber to prevent the arcing issue in the plasma processing procedures.

2. Description of the Related Art

In the semiconductor fabrication, wafer is generally fixed at an electrostatic chuck, and a plasmas chamber is utilized for depositing a material on or etching the wafer. FIG. 1 is a schematic diagram illustrating part of a configuration of a wafer positioned on an electrostatic chuck of a conventional wafer processing chamber. In the conventional wafer processing chamber, a wafer 11 is positioned on a mounting table of an electrostatic chuck 10, the mounting table comprises a conductive plate 102, an electrode 103 on the conductive plate 102 and an insulating layer 104. The electrode 103 is disposed between the conductive plate 102 and the insulating layer 104, and embedded in the insulating layer 104. The wafer 11 is loaded on a focus ring 13 above the insulating layer 104.

Also, at least one lift pin 15 is positioned under the wafer 11, and promoted up-and-down through a corresponding lift pin hole for lifting the wafer 11 up-and-down. FIG. 2 is a schematic top view illustrating a wafer in a conventional wafer processing chamber lifted by three lift pins.

A DC voltage is applied to the electrostatic chuck 10 from a DC power supply (non-illustrated) connected with the electrode 103. Accordingly, the wafer 11 is electrostatically attracted to and held on the electrostatic chuck 10. Therefore, the wafer 11 is chucked onto the insulating layer 104.

In a plasma etching process, an etching gas is injected into the processing chamber, a first RF power is applied (from a power source not illustrative) to generate a plasma, and a second RF power is applied to the conductive plate 102 so that the ions of the plasma can collide against the wafer 11. The application of the second RF power is desirable to a plasma etching process such as a reactive ion etching (RIE). Moreover, a clamping force between the wafer 11 and the insulating layer 104 increases due to the self-bias.

As shown in FIG. 1 and FIG. 2, those lift pins 15 are positioned under the wafer 11. In a wafer-transferring process, the lift pins 15 may contact the bottom surface of the wafer 11 when lifting the wafer up-and-down. In this conventional electrostatic chuck, an arc is generated at one end of the lift pin 15 or the lift pin hole when the second RF power is applied to the conductive plate 102. Arcing is a common problem in the plasma processing systems for various reasons. For example, a cooling gas (such as He gas) supplied through an injection hole flows to the lift pin hole, thereby generating the arc at the end of the lift pin hole close to the bottom surface of the wafer. If the cooling gas near the end of the lift pin hole is heated by a temperature increase of the wafer 11, a plasma discharge generated at the lift pin hole would cause damage to the wafer 11 and the electrostatic chuck 10.

As shown in FIG. 2, the arcing defects are typically observed on the surface of the wafer at which are corresponding to the lift pins 15. The arcing defects have considerable effects on various process parameters, such as the deposition and/or etch rates, thereby causing non-uniformities on the wafer. Also, the yield of products manufactured by the wafers having arcing defects would be reduced. Thus, it is desirable to develop a method or apparatus for preventing the arcing defects effectively. A known method has been proposed by enlarging the pin hole, but this would cause another considerable issue of polymer accumulation in the pin hole during wafer processing.

### SUMMARY

The disclosure is directed to a wafer processing chamber and a method for transferring wafer in the same. In the embodiment, a wafer processing chamber with improved electrostatic chuck is provided, and the arcing issue could be effectively prevented in the wafer processing procedures, thereby improving the electrical properties of the device fabricated on the wafer of the embodiment.

According to the disclosure, a method for transferring wafer in process chamber, comprising providing a focus ring and a lifting apparatus positioned corresponding to the focus ring; setting a wafer on the focus ring; lifting the wafer and the focus ring together by the lifting apparatus; and transferring the wafer and the focus ring together by a transferring unit.

According to the disclosure, a wafer processing chamber is provided, at least comprising a processing platform; a focus ring disposed above the processing platform for setting a wafer, and a lifting apparatus coupled to the processing platform and positioned corresponding to the focus ring; wherein the focus ring is moved by the lifting apparatus for lifting the wafer and the focus ring up and down together.

### BRIEF DESCRIPTION OF THE DRAWINGS

FIG. 1 is a schematic diagram illustrating part of a configuration of a wafer positioned on an electrostatic chuck of a conventional wafer processing chamber.

FIG. 2 is a schematic top view illustrating a wafer in a conventional wafer processing chamber lifted by three lift pins.

FIG. 3 is a schematic diagram illustrating part of a configuration of a wafer positioned on an electrostatic chuck of a wafer processing chamber according to a first embodiment of the present disclosure.

FIG. 4A is a schematic diagram illustrating a wafer in a setting-position on an electrostatic chuck of a wafer processing chamber according to the first embodiment of the present disclosure.

FIG. 4B is a schematic diagram illustrating a wafer in a lifting-position on an electrostatic chuck of a wafer processing chamber according to the first embodiment of the present disclosure.

FIG. 5A˜FIG. 5E schematically illustrate a method for transferring a wafer in a wafer processing chamber according to the first embodiment of the present disclosure.

FIG. 6 is a schematic diagram illustrating part of a configuration of a wafer positioned on an electrostatic chuck of a wafer processing chamber according to a second embodiment of the present disclosure.

FIG. 7A is a schematic diagram illustrating a wafer in a setting-position on an electrostatic chuck of a wafer processing chamber according to the second embodiment of the present disclosure.

FIG. 7B is a schematic diagram illustrating a wafer in a lifting-position on an electrostatic chuck of a wafer processing chamber according to the second embodiment of the present disclosure.

FIG. 8A˜FIG. 8C are schematic diagrams illustrating a wafer positioned on an electrostatic chuck of a wafer processing chamber being transferred by a mechanical assembly according to a third embodiment of the present disclosure.

FIG. 9A and FIG. 9B are top views of a lifting apparatus having clutch arms according to the third embodiment of the present disclosure, showing clutch arms extending outwardly and clutching the focus ring, respectively.

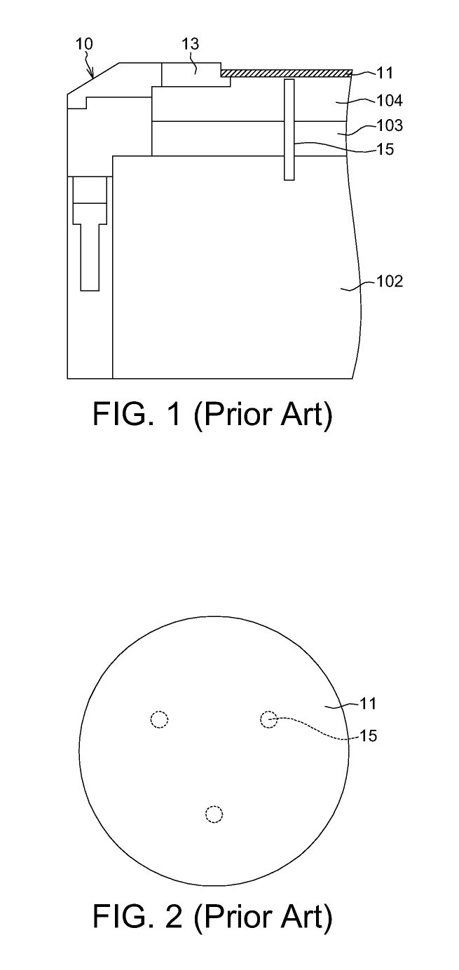

### DETAILED DESCRIPTION

In the present disclosure, a wafer processing chamber and a method for transferring wafer in the same are provided. In the embodiment, a wafer processing chamber with improved electrostatic chuck is provided to prevent the arcing issue in the plasma processing procedures. The embodiments are described in details with reference to the accompanying drawings. The identical and/or similar elements of the embodiments are designated with the same and/or similar reference numerals. Also, it is also important to point out that the illustrations may not be necessarily be drawn to scale, and that there may be other embodiments of the present disclosure which are not specifically illustrated. Thus, the specification and the drawings are to be regard as an illustrative sense rather than a restrictive sense.

In the present disclosure, a lifting apparatus positioned outside the wafer, such as positioned corresponding to the focus ring, is provided. In the embodiments, the focus ring is moved by the lifting apparatus for lifting the wafer and the focus ring up and down together. The lifting apparatus of the embodiment could be set below or above the focus ring. Some embodiments are disclosed below. However, it is noted that other embodiments with modified or different configurations, which could be varied depending on the actual needs of the applications, are also applicable. Thus, the accompanying drawings are depicted only for demonstration, not for limitation.

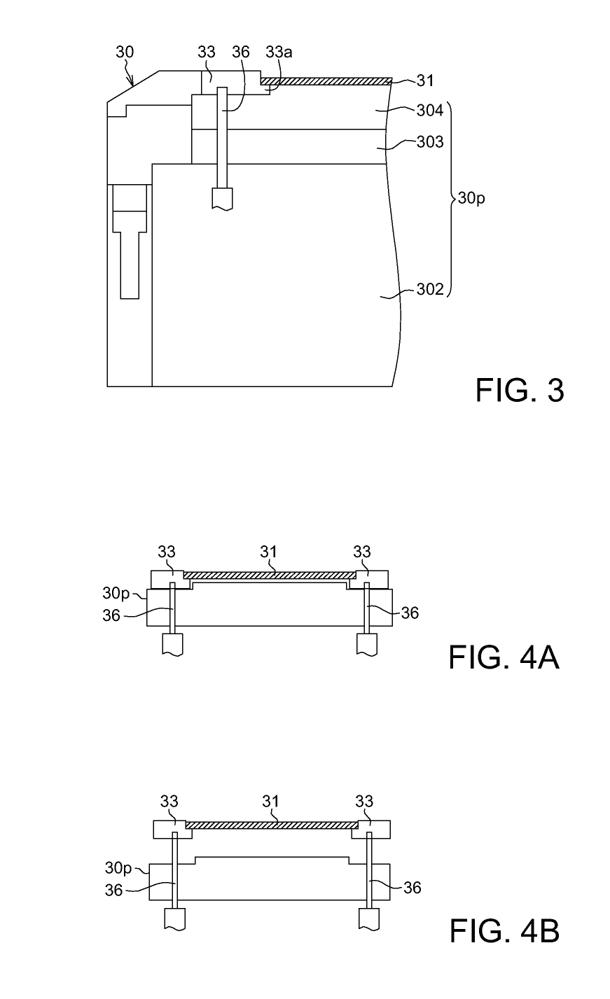

FIG. 3 is a schematic diagram illustrating part of a configuration of a wafer positioned on an electrostatic chuck of a wafer processing chamber according to a first embodiment of the present disclosure. A wafer processing chamber has an electrostatic chuck 30 which at least comprises a processing platform 30p, a focus ring 33 disposed above the processing platform 30p for setting a wafer 31, and a lifting apparatus 36 coupled to the processing platform 30p and positioned corresponding to the focus ring 33. The focus ring 33 is moved by the lifting apparatus 36 for lifting the wafer 31 and the focus ring 33 up and down together.

In one embodiment, the processing platform 30p comprises a conductive plate 302, an electrode 303 and an insulating layer 304, wherein the electrode 303 is disposed between the conductive plate 302 and the insulating layer 304, and embedded in the insulating layer 304. The wafer 31 is loaded on a focus ring 33 above the insulating layer 304. A DC voltage from a DC power supply (non-illustrated) connected with the electrode 303 is applied to the processing platform 30p, thereby electrostatically chucking the wafer 31 onto the insulating layer 304.

In a plasma etching process, an etching gas is injected into the processing chamber, a first RF power is applied (from a power source not illustrative) to generate a plasma, and a second RF power is applied to the conductive plate 302 so that the ions of the plasma can collide against the wafer 31.

In the first embodiment, the focus ring 33 is provided on the peripheries of the wafer 31, and may have a protruding rim 33a for supporting the wafer 31. When the wafer 31 is loaded on the processing platform 30p, the peripheral edge of the wafer 31 is placed against the protruding rim 33a of the focus ring 33. Thus, the focus ring 33 of the first embodiment functions as a wafer carrier.

As shown in FIG. 3, the lifting apparatus 36 of the first embodiment is positioned below the focus ring 33. Compared to the conventional wafer processing chamber, no object (such as lift pins 15) be disposed near the bottom surface of the wafer in the wafer processing chamber of the embodiment, thereby preventing the arcing defects in the wafer processing procedure, such as plasma etching process. Examples of the lifting apparatus of the embodiment include a mechanical assembly (such as projectable and retractable pins), a magnetic assembly, or other applicable apparatus capable of promoting an up-and-down movement of the focus ring 33.

FIG. 4A is a schematic diagram illustrating a wafer in a setting-position on an electrostatic chuck of a wafer processing chamber according to the first embodiment of the present disclosure, wherein the lifting apparatus 36 is in a retracted state, and the focus ring 33 with the wafer 31 positioned thereon are in a first position such as a setting-position. FIG. 4B is a schematic diagram illustrating a wafer in a lifting-position on an electrostatic chuck of a wafer processing chamber according to the first embodiment of the present disclosure, wherein the lifting apparatus 36 is in a projected state, and the focus ring 33 with the wafer 31 positioned thereon are in a second position such as a lifting-position. Thus, the focus ring 33 is moved by the lifting apparatus 36 for lifting the wafer 31 and the focus ring 33 up and down together according to the embodiment. As clearly shown in FIG. 4A and FIG. 4B, no object (such as lift pins 15) is disposed under the wafer 31 for directly contacting or very close to the bottom surface of the wafer 31 in the wafer processing chamber of the embodiment.

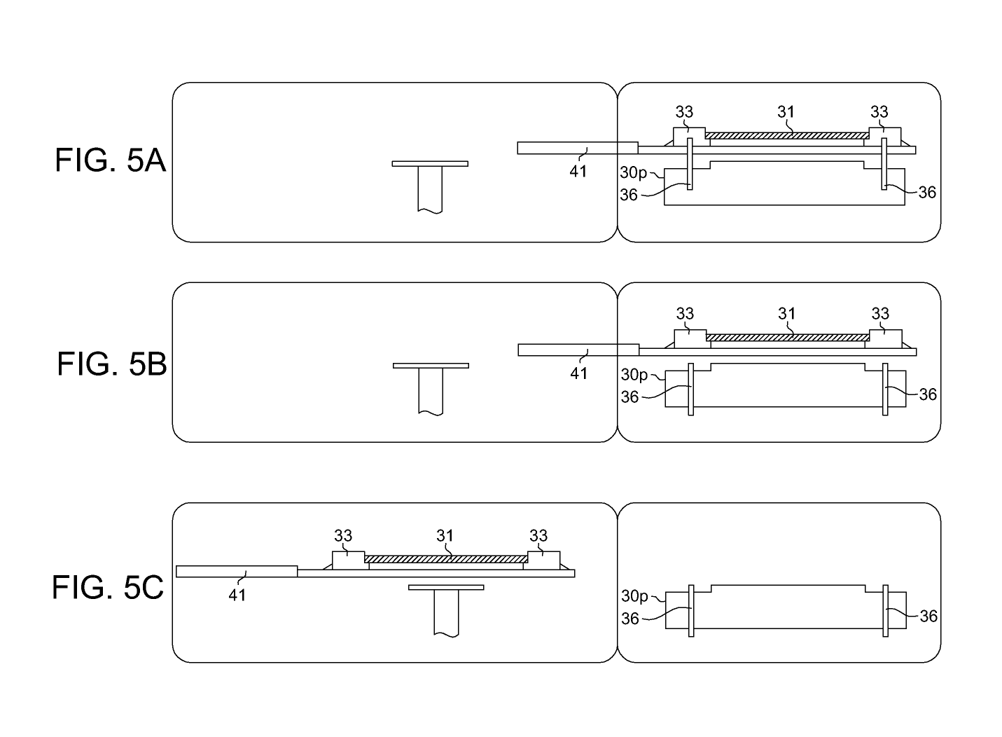

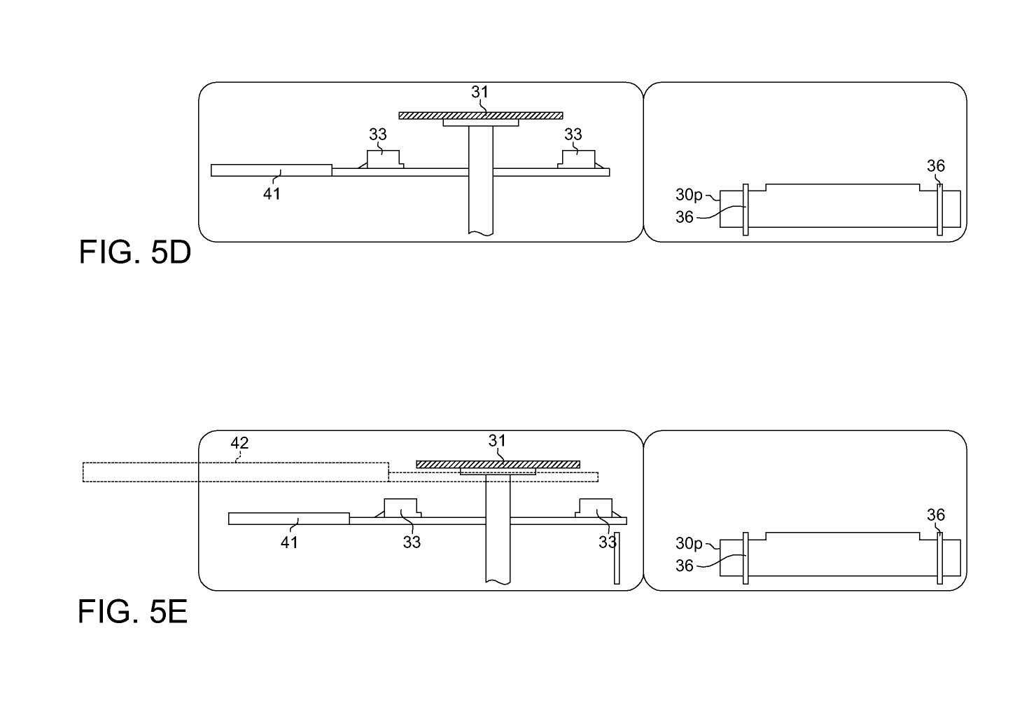

FIG. 5A˜FIG. 5E schematically illustrate a method for transferring a wafer in a wafer processing chamber according to the first embodiment of the present disclosure. In the first embodiment, the lifting apparatus 36 positioned under the focus ring 33. Other configurations of the wafer processing chamber of the first embodiment have been described above, which are not redundantly repeated. The wafer processing chamber according to the first embodiment further comprises a transferring unit coupled to a control unit (not illustrated) to which the processing platform 30p is electrically connected. In one embodiment, the transferring unit could be in a form of a transfer arm 41. As shown in FIG. 5A, the wafer 31 and the focus ring 33 are lifted together by the lifting apparatus 36, and the transfer arm 41 is moved to the space under the wafer 31 for carrying the wafer 31 and the focus ring 33 together. In FIG. 5A, the lifting apparatus 36 is in a projected state. As shown in FIG. 5B, the lifting apparatus 36 is retracted back to a retracted state. As shown in FIG. 5C, the wafer 31 and the focus ring 33 are transferred together to a loadlock by the transfer arm 41. As shown in FIG. 5D, the focus ring 33 is separated from the wafer 31, and the wafer 31 is left on the loadlock for performing subsequent procedures. As shown in FIG. 5E, another arm 42 may be driven to pick up the wafer 31 after the processing procedures have been down. The focus ring 33 on the transfer arm 41 would be transferred back to the processing chamber for loading another wafer, and the steps of FIG. 5A˜FIG. 5E would be repeated.

Although the lifting apparatus 36 positioned under the focus ring 33 is illustrated in the first embodiment, the disclosure is not limited thereto. The lifting apparatus 36 could be positioned above the focus ring 33, and lifts up the focus ring 33 by a mechanical assembly, a magnetic assembly, or other applicable apparatus which is capable of promoting an up-and-down movement of the focus ring 33 with the wafer 31. In one embodiment, the lifting apparatus may contact an upper surface the focus ring for lifting the wafer and the focus ring up together.

In the following description, a magnetic assembly is applied as one of the lifting apparatus 36.

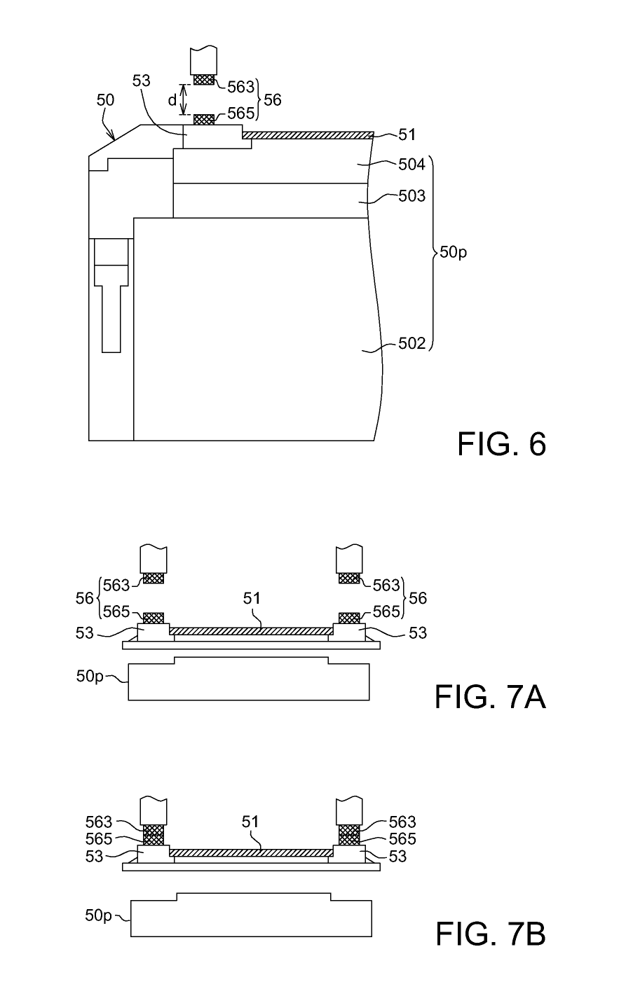

FIG. 6 is a schematic diagram illustrating part of a configuration of a wafer positioned on an electrostatic chuck of a wafer processing chamber according to a second embodiment of the present disclosure. A wafer processing chamber has an electrostatic chuck 50 which at least comprises a processing platform 50p, a focus ring 53 disposed above the processing platform 50p for setting a wafer 51, and a lifting apparatus 56 coupled to the processing platform 50p and positioned corresponding to the focus ring 53. The focus ring 53 is moved by the lifting apparatus 56 for lifting the wafer 51 and the focus ring 53 up and down together.

In the second embodiment, the lifting apparatus 56 comprises a first magnetic unit 563 and a second magnetic unit 565. The first magnetic unit 563 is disposed above the focus ring 53, and the second magnetic unit 565 is disposed on the upper surface of the focus ring 53. Also, wafer loading and/or unloading procedures are not disturbed by the positions of the first magnetic unit 563 and the second magnetic unit 565.

FIG. 7A is a schematic diagram illustrating a wafer in a setting-position on an electrostatic chuck of a wafer processing chamber according to the second embodiment of the present disclosure, wherein the lifting apparatus 56 is in a magnetic-repelling state, and the focus ring 53 with the wafer 51 positioned thereon are in a first position such as a setting-position. As shown in FIG. 7A, the first magnetic unit 563 is spaced apart from the focus ring 53 at a distance d when the focus ring 53 and wafer 51 are positioned in the setting-position. Meanwhile, there could be an magnetic repelling force between the first magnetic unit 563 and the second magnetic unit 565, which may be facilitate to positioning the focus ring 53. For example, both of the first magnetic unit 563 and the second magnetic unit 565 have the same polarity, i.e. both with magnetic polarity N or S. Alternatively, there could be no magnetic force between the first magnetic unit 563 and the second magnetic unit 565. The details of implementation could be modified or changed according to the design requirements of the practical applications.

FIG. 7B is a schematic diagram illustrating a wafer in a lifting-position on an electrostatic chuck of a wafer processing chamber according to the second embodiment of the present disclosure, wherein the lifting apparatus 56 is in a magnetic-attracting state, and the focus ring 53 with the wafer 51 positioned thereon are in a second position such as a lifting-position. When the opposite polarities are created (ex: by using electric current) on the first magnetic unit 563 and the second magnetic unit 565, i.e, one having magnetic polarity N(/S) and the other having magnetic polarity S(/N), the first magnetic unit 563 and the second magnetic unit 565 are attracted to each other, thereby lifting the focus ring 53 and wafer 51 upwardly to reach the lifting-position, as shown in FIG. 7B.

Accordingly, the lifting apparatus 56 of the second embodiment is capable of lifting the wafer 51 and the focus ring 53 up and down together due to the magnetic attraction force and magnetic repellant force (/or no magnetic force). Therefore, the first magnetic unit 563 and the second magnetic unit 565 of the second embodiment are not necessary to be the permanent magnets, and the polarities thereof could be changed depending on the different states for setting or transferring the focus ring 53.

As clearly shown in FIG. 7A and FIG. 7B, no object (such as lift pins 15) is disposed under or above the wafer 51 for directly contacting or very close to the bottom or upper surface of the wafer 51 in the wafer processing chamber of the embodiment, thereby effectively preventing the arcing defects.

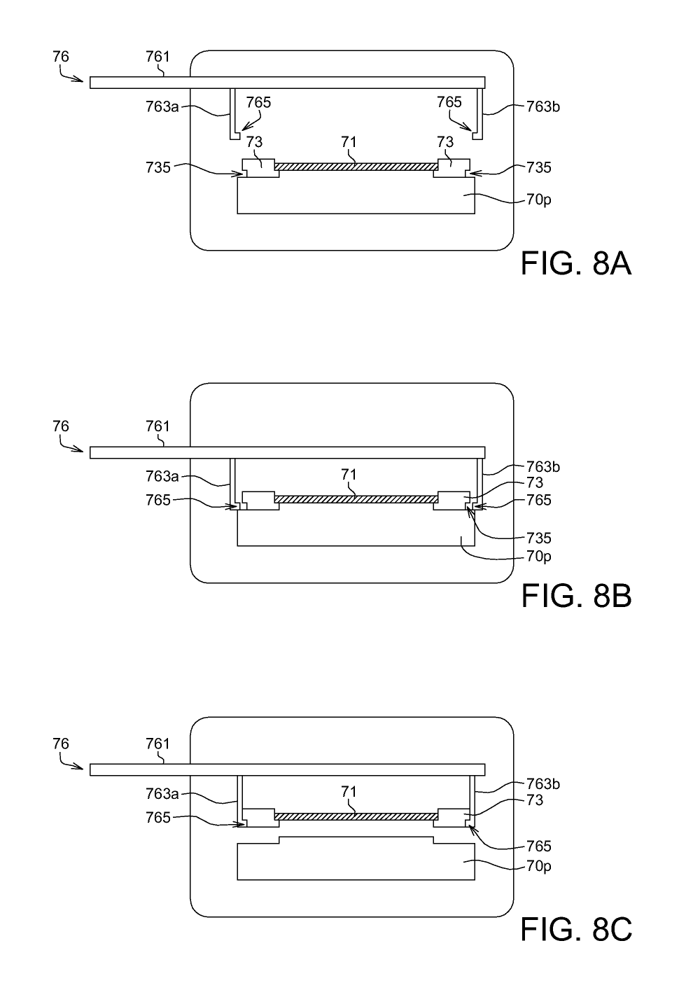

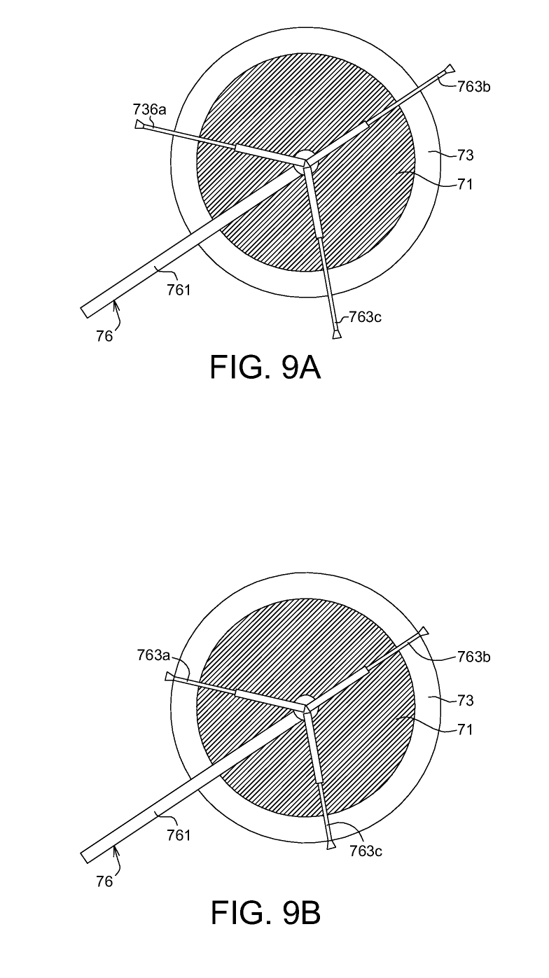

FIG. 8A˜FIG. 8C are schematic diagrams illustrating a wafer positioned on an electrostatic chuck of a wafer processing chamber being transferred by a mechanical assembly according to a third embodiment of the present disclosure. In the third embodiment, the lifting apparatus 76 is a mechanical assembly with clutch arms is provided for transferring the wafer positioned on an electrostatic chuck. FIG. 9A and FIG. 9B are top views of a lifting apparatus having clutch arms according to the third embodiment of the present disclosure, showing clutch arms extending outwardly and clutching the focus ring, respectively.

Similarly, a wafer processing chamber has an electrostatic chuck which at least comprises a processing platform 70p, a focus ring 73 disposed above the processing platform 70p for setting a wafer 71. The lifting apparatus 76 of the third embodiment is coupled to the processing platform 70p and positioned above to the focus ring 73. The focus ring 73 is moved by the lifting apparatus 76 for lifting the wafer 71 and the focus ring 73 up and down together. Also, the wafer loading and/or unloading procedures are not disturbed by the positions of the lifting apparatus 76.

Please refer to FIG. 8A˜FIG. 8C, FIG. 9A and FIG. 9B together. The lifting apparatus 76 of the third embodiment comprises a cantilever beam 761 and three clutch arms 763a, 763b and 763c connected to the cantilever beam 761. As shown in FIG. 8A˜FIG. 8C, each end of the clutch arms 763a, 763b and 763c includes a protrusion 765 (projected from the clutch arms 763a, 763b and 763c and towards the focus ring 73). In the third embodiment, a groove 735 is formed at the outer surface of the focus ring 73, and the shape and position of the groove 735 are corresponding to that of the protrusions 765 at the ends of the clutch arms 763a, 763b and 763c. For example, the groove 735 is positioned at, but not limited to, the lower portion of the focus ring 73. It is understood for people skilled in the art that shapes and positions of the groove 735 and the protrusions 765 could be modified or changed according to the practical applications, and the disclosure is not limited to the configuration as depicted in the drawings.

As shown in FIG. 8A, the lifting apparatus 76 positioned above the focus ring 73 and the wafer 71 is in an off-state, and the clutch arms 763a, 763b and 763c extend outwardly. Meanwhile, the focus ring 73 with the wafer 71 positioned thereon are in a first position such as a setting-position. As shown in FIG. 9A, the ends of three clutch arms 763a, 763b and 763c exceed the periphery of the focus ring 73. Also, the wafer 71 has been virtually divided into three equal parts by the clutch arms 763a, 763b and 763c. It is noted that the number of clutch arms are limited to three, and more clutch arms are also applicable if they are able to catch and move the focus ring 73 and the wafer 71 up and down steadily.

When it is a need to transfer the focus ring 73 and the wafer 71, the lifting apparatus 76 is moved downwardly for approaching the focus ring 73, as shown in FIG. 8B. In one embodiment, movement of the lifting apparatus 76 stops when the protrusions 765 are positioned correspondingly to the groove 735 of the focus ring 73.

When the clutch arms 763a, 763b and 763c retract inwardly and engage with the groove 735, the focus ring 73 with the wafer 71 thereon are ready to be lifted and transferred. As shown in FIG. 8C and FIG. 9B, the lifting apparatus 76 is in an on-state, and the clutch arms 763a, 763b and 763c engage with the groove 735 of the focus ring 73. The focus ring 73 with the wafer 71 thereon is lifted up to a second position such as a lifting-position by the lifting apparatus 76.

According to the aforementioned descriptions, the provided wafer processing chamber and the methods for transferring wafer utilize a lifting apparatus outside the region of wafer, such as corresponding to the focus ring, thereby effectively preventing the arcing issue in the wafer processing procedures, and also have no other issue such as polymer accumulation problem. The electrical properties of the device on the wafer manufactured by the wafer processing chamber and method according to the embodiments could be greatly improved consequently.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for transferring wafer in process chamber, comprising:
providing a focus ring and a lifting apparatus positioned corresponding to the focus ring;
setting a wafer on the focus ring;
lifting the wafer and the focus ring together by the lifting apparatus; and
transferring the wafer and the focus ring together by a transferring unit.

2. The method according to claim 1, wherein the lifting apparatus is positioned below the focus ring.

3. The method according to claim 2, wherein the lifting apparatus contacts a bottom surface of the focus ring for lifting the wafer and the focus ring up together.

4. The method according to claim 2, wherein when the lifting apparatus is in a retracted state, the focus ring with the wafer thereon are positioned in a first position; when the lifting apparatus is in a projected state, the focus ring with the wafer thereon are positioned in a second position higher than the first position.

5. The method according to claim 1, wherein the lifting apparatus comprises a plurality of lift pins.

6. The method according to claim 1, wherein the lifting apparatus is positioned above the focus ring.

7. The method according to claim 6, wherein the lifting apparatus contacts an upper surface the focus ring for lifting the wafer and the focus ring up together.

8. The method according to claim 1, wherein the lifting apparatus comprises a magnetic assembly.

9. The method according to claim 8, wherein the lifting apparatus comprises a first magnetic unit disposed above the focus ring, and a second magnetic unit disposed on the upper surface of the focus ring.

10. The method according to claim 9, wherein when the lifting apparatus is in a magnetic-repelling state or no magnetic field generated for the lifting apparatus, the focus ring with the wafer thereon are positioned in a first position; when the lifting apparatus is in a magnetic-attracting state, the focus ring with the wafer thereon are positioned in a second position higher than the first position.

11. The method according to claim 1, wherein the lifting apparatus is positioned above the focus ring.

12. The method according to claim 11, wherein the lifting apparatus comprises a cantilever beam and three clutch arms connected to the cantilever beam, and the clutch arms clutch the focus ring for lifting the wafer and the focus ring together.

13. The method according to claim 12, wherein a protrusion is formed at each end of the clutch arms, and a groove is formed at an outer surface of the focus ring, wherein the clutch arms clutch the focus ring by engaging the protrusions with the groove.

14. A wafer processing chamber, at least comprising:
a processing platform;
a focus ring, disposed above the processing platform for setting a wafer; and
a lifting apparatus, coupled to the processing platform and positioned corresponding to the focus ring;
wherein the focus ring is moved by the lifting apparatus for lifting the wafer and the focus ring up and down together.

15. The wafer processing chamber according to claim 14, wherein the lifting apparatus is positioned below the focus ring.

16. The wafer processing chamber according to claim 15, wherein the lifting apparatus contacts a bottom surface of the focus ring for lifting the wafer and the focus ring up together.

17. The wafer processing chamber according to claim 14, wherein the lifting apparatus is positioned above the focus ring.

18. The wafer processing chamber according to claim 17, wherein the lifting apparatus contacts an upper surface the focus ring for lifting the wafer and the focus ring up together.

19. The wafer processing chamber according to claim 14, wherein the lifting apparatus comprises a plurality of lift pins.

20. The wafer processing chamber according to claim 14, wherein the lifting apparatus comprises a magnetic assembly.

21. The wafer processing chamber according to claim 20, wherein the lifting apparatus comprises a first magnetic unit disposed above the focus ring, and a second magnetic unit disposed on the upper surface of the focus ring, wherein the lifting apparatus is in a magnetic-attracting state by applying opposite polarities to the first magnetic unit and the second magnetic unit.

22. The wafer processing chamber according to claim 14, wherein the lifting apparatus is positioned above the focus ring.

23. The wafer processing chamber according to claim 22, wherein the lifting apparatus comprises a cantilever beam and three clutch arms connected to the cantilever beam, and the clutch arms clutch the focus ring for lifting the wafer and the focus ring together.

24. The wafer processing chamber according to claim 23, wherein a protrusion is formed at each end of the clutch arms, and a groove is formed at an outer surface of the focus ring, wherein the clutch arms clutch the focus ring by engaging the protrusions with the groove.

25. The wafer processing chamber according to claim 14, wherein the focus ring comprises a protruding rim for placing an edge of the wafer.

26. The wafer processing chamber according to claim 14, further comprising a transferring unit coupled to the processing platform to transfer the wafer and the focus ring together.
